(19) United States
(12) Patent Application Publication
(10) Pub. No.: US 2026/0005165 A1
(43) Pub. Date: Jan. 1, 2026

(54) ENCLOSURES FOR INTEGRATED CIRCUITS

(71) Applicant: BAE SYSTEMS Information and Electronic Systems Integration Inc., Nashua, NH (US)

(72) Inventors: Robert P. Taylor, Bedford, NH (US); Christopher A. Palatino, Nashua, NH (US); Douglas M. Dugas, Chelmsford, MA (US); Thomas C. Reese, Arlington, MA (US); Michael Litchfield, Merrimack, NH (US); Christopher R. Bye, Bedford, NH (US)

(73) Assignee: BAE SYSTEMS Information and Electronic Systems Integration Inc., Nashua, NH (US)

(21) Appl. No.: 18/760,902

(22) Filed: Jul. 1, 2024

(51) Int. Cl. H01L 23/66; H01L 23/31; H01Q 1/22

(52) U.S. Cl. CPC H01L 23/66; H01L 23/3107; H01Q 1/2283; H01L 2223/6627; H01L 2223/6638; H01L 2223/6644

(57) ABSTRACT

A system includes a first enclosure, a first input transmission line within the first enclosure, a first output transmission line within the first enclosure, and first one or more die within the first enclosure and laterally between the first input and first output transmission lines. The system further includes a second enclosure including conductive material, a second input transmission line within the second enclosure, a second output transmission line within the second enclosure, and second one or more die within the second enclosure and laterally between the second input and second output transmission lines. Dimensions of the first enclosure is substantially same as (e.g., within 2%) that of the second enclosure. A length of the first input transmission line differs from a length of the second input transmission line by at least 5%, the lengths being measured in a direction parallel to the lengths of the first and second enclosures.

### FIELD OF DISCLOSURE

The present disclosure relates to integrated circuit (IC) die, and more particularly, to enclosures for IC die.

### BACKGROUND

Integrated circuit die are used in many different applications, including radio frequency (RF) applications. Several integrated circuit packages including one or more die can be mounted on a circuit board, such as a printed circuit board (PCB). Alternatively, integrated circuit die (such as bare die without the integrated circuit packaging and/or integrated circuit die within corresponding integrated circuit packages) may be mounted and packaged within an enclosure, where the enclosure may also include one or more other components, such as passive components (e.g., resistors, capacitors, and/or inductors) and heat spreaders.

### BRIEF DESCRIPTION OF THE DRAWINGS

FIGS. 1A, 1B, 1C, 1D, 1E, and 1F schematically illustrate various view of an apparatus comprising (i) an enclosure, (ii) an input microstrip within the enclosure, (iii) an output microstrip within the enclosure, and (iv) one or more integrated circuit die within the enclosure and laterally between the input microstrip and the output microstrip, in accordance with an embodiment of the present disclosure.

FIGS. 2A and 2B schematically illustrate various views of another apparatus comprising (i) an enclosure, (ii) an input microstrip within the enclosure, (iii) an output microstrip within the enclosure, and (iv) one or more integrated circuit die within the enclosure and laterally between the input microstrip and the output microstrip, in accordance with an embodiment of the present disclosure.

FIG. 3 illustrates a system including the apparatus of FIGS. 1A-1F and the apparatus of FIGS. 2A-2B, in accordance with an embodiment of the present disclosure.

FIG. 4 illustrates a flowchart depicting a method of designing and forming any of the apparatus of FIGS. 1A-2B, in accordance with an embodiment of the present disclosure.

Although the following detailed description will proceed with reference being made to illustrative examples, many alternatives, modifications, and variations thereof will be apparent in light of this disclosure.

### DETAILED DESCRIPTION

There remain a number of nontrivial issues with packaging integrated circuit die within an enclosure. For example, a first application may require a relatively high number of integrated circuit die and/or integrated circuit die having relatively large lengths to be packaged within a relatively large enclosure; and a second application may require a relatively lower number of integrated circuit die and/or integrated circuit die having relatively small lengths to be packaged within a relatively smaller enclosure. Thus, different sized enclosures are used to accommodate different number of integrated circuit die and/or different sized integrated circuit die. This variance in packaging adds complexity and cost to manufacturing, and further complicates downstream manufacturing due to the need to accommodate the different packaging sizes. For instance, if a given package is placed in a certain location within a higher assembly chassis, then a change in that package size may further necessitate a change in design at the chassis level.

Accordingly, techniques are described herein to use uniformly sized enclosures for various different applications that use different quantities and/or different sized integrated circuit die. Thus, two enclosures, having identical or otherwise substantially the same dimensions, may be used for first and second applications within a given higher level system. Because the packaging footprint (e.g., dimensions and input/output scheme) remains constant regardless of the packaging contents, swapability at the system level is greatly simplified, as is retrofit capability. For example, a first enclosure may be used for the first application to accommodate the relatively higher number of integrated circuit die and/or integrated circuit die having relatively small lengths within the first enclosure, and a second enclosure may be used for the second application to accommodate the relatively lower number of integrated circuit die and/or integrated circuit die having relatively large lengths within the second enclosure, where the first and second enclosures have substantially the same footprint, including dimensions, as well as other features define by the enclosures, such as the same inputs and outputs (e.g., for receiving and providing signals and/or power), and the same fastener scheme (e.g., bolt hole pattern). Thus, same dimensioned enclosures can be universally used for many different applications involving different number of die and/or IC packages. This modular approach makes the enclosures scalable, easily swapable, easily replaceable, and easily repairable. In one embodiment, dimensions (such as lengths, widths, heights described below) of the first and second enclosures are identical or otherwise substantially the same, such as within 1% or 2% of each other (or other acceptable tolerance, for a given system). Thus, an enclosure that is of a fixed physical dimension may house several die and/or integrated circuit packages. An enclosure, deliberately oversized to house the die and/or the IC packages, allows for different physically dimensioned die and/or integrated circuit packages to be placed within the same enclosure, thereby improving versatility. With an oversized enclosure, re-use of the enclosure for different applications by using die or integrated circuit packages with unique electrical characteristics and dimensions is possible, without changing the enclosure each time. An oversized enclosure is scalable in volume to include a large number of different electrical characteristics, allowing for modularity yet still occupying the same enclosure physical dimensions.

The enclosures and the integrated circuit die therewithin may be used for any different applications, and may advantageously be used for RF applications. For example, RF signal transmission within the enclosure may be over an input microstrip and an output microstrip. As will be appreciated in light of this disclosure, reference to microstrips is also intended to include other types of transmission lines, such as strip lines, through lines, and/or RF input or output pins, for example. To this end, the use of a specific type of transmission line (such as microstrip) is not intended to limit the present description to that specific type of transmission line. Rather, the techniques provided herein can benefit any type of transmission lines, whether those transmission lines be microstrips, or strip lines, through lines, or and/or RF input or output pins, or any other type of transmission lines. In an example, the enclosure includes an input port to receive a RF input signal, and an output port to output a RF output signal. The one or more integrated circuit die within the enclosure are laterally between the input microstrip and the output microstrip. For example, the input microstrip provides the RF input signal from the input port to the one or more integrated circuit die, and the output microstrip provides the RF output signal from the one or more integrated circuit die to the output port. In another example, RF signal transmission internal to the enclosure may start with the RF input pin to integrated circuit die directly. A collection of substrates and additional integrated circuit die may follow laterally, leading to the RF output pin. The die may be placed next to the RF output pin for direct interface. The enclosure is made of conductor material (such as one or more metals and/or alloys thereof) and may be sealed to provide hermeticity.

In an example, due to the fixed dimension of the enclosure, a length between the input port and the output port of the enclosure is fixed, whereas a length of the one or more integrated circuit die within the enclosure may vary from one application to another, where different sized and/or different number of integrated circuit die may be used. Accordingly, in an example, a length of the input microstrip and/or a length of the output microstrip may be configurable, e.g., to account for the varying lengths of the one or more integrated circuit die within the enclosure. For example, if two relatively large sized integrated circuit die having relatively large lengths are to be accommodated within a first enclosure, the lengths of the input microstrip and/or the output microstrip within the first enclosure may be made relatively smaller. On the other hand, if two relatively smaller sized die (or a single die) having relatively small lengths are to be accommodated within a second enclosure, the lengths of the input microstrip and/or the output microstrip within the first enclosure may be made correspondingly larger, where the first and second enclosures have substantially the same dimensions. Thus, the lengths of the input microstrip and/or the output microstrip are designed according to the lengths of the one or more integrated circuit die to be placed within am enclosure having the fixed dimensions. Thus, the enclosure is made relatively oversized, so as to fit various sized and/or various number of integrated circuit die, and the lengths of the input microstrip and/or the output microstrip are tuned, so that the integrated circuit die can be accommodated within the enclosure. Numerous configurations and variations will be apparent in light of this disclosure.

### Architecture

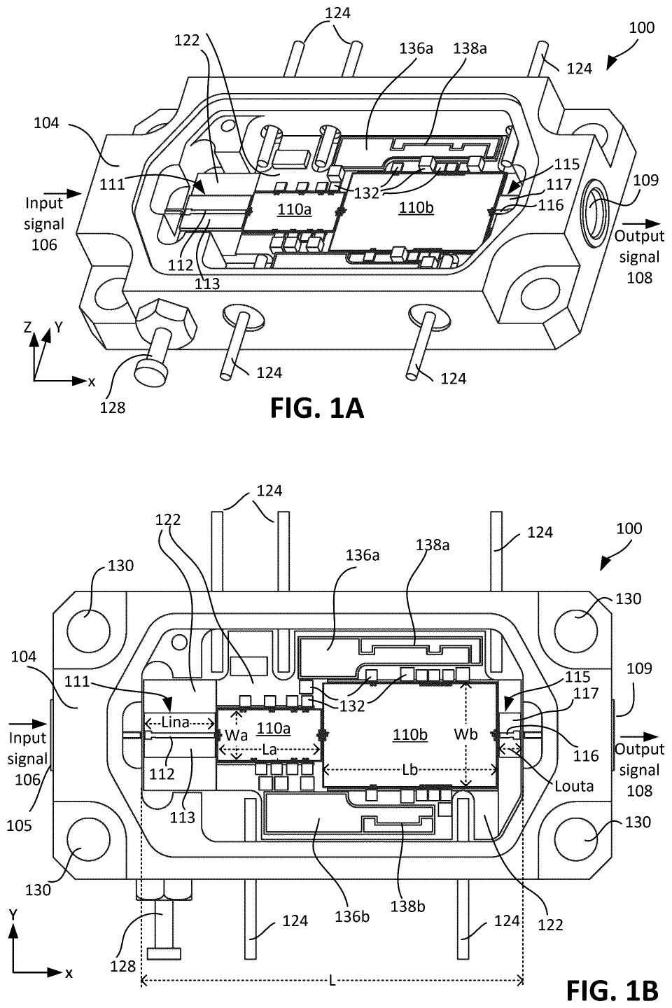

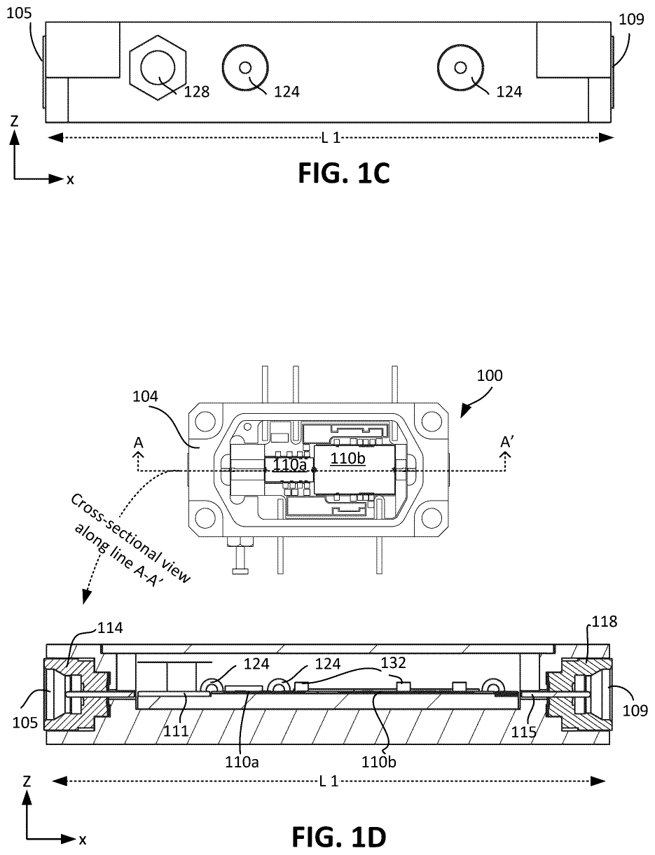

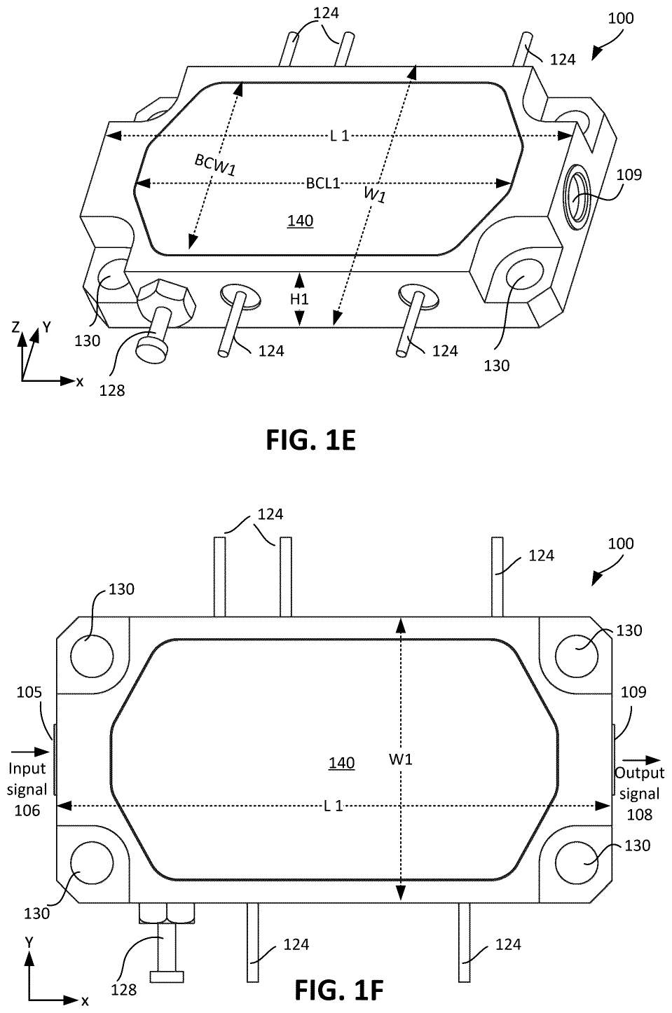

FIGS. 1A, 1B, 1C, 1D, 1E, and 1F schematically illustrate various view of an apparatus 100 comprising (i) an enclosure 104, (ii) an input microstrip 111 within the enclosure 104, (iii) an output microstrip 115 within the enclosure 104, and (iv) one or more integrated circuit die 110a, 110b within the enclosure 104 and laterally between the input microstrip 110 and the output microstrip 115, in accordance with an embodiment of the present disclosure.

Specifically, FIG. 1A illustrates an isometric view of the apparatus 100, without a cover 140 of the enclosure 104 (such that components within the enclosure 104 are visible). FIG. 1B illustrates a plan view of the apparatus 100, also without the cover 140 of the enclosure 104. FIG. 1C illustrates a side view of the apparatus 100. FIG. 1D illustrates a cross-sectional view of the apparatus 100 along line A-A′ of the apparatus 100 (where line A-A′ is illustrated in a zoomed out view of the apparatus 100 at an upper portion of FIG. 1D, and the cross-sectional view of the apparatus 100 is illustrated at a lower portion of FIG. 1D). FIG. 1E illustrates an isometric view of the apparatus 100, with the cover 140 of the enclosure 104 in place (such that one or more components within the enclosure 104, which were visible in FIG. 1A, are not visible in FIG. 1E). FIG. 1F illustrates a plan view of the apparatus 100, also with the cover 140 of the enclosure 104 in place (such that one or more components within the enclosure 104, which were visible in FIG. 1B, are not visible in FIG. 1F).

The apparatus 100 includes the enclosure 104, which is a housing for the components there within. In an example, the body of the enclosure 104 comprises conductive material, such as one or more metals and/or alloys thereof. In an example, the enclosure 104 comprises aluminum. In an example, the apparatus 100 (e.g., the enclosure 104 and cover 140) is hermetically sealed, e.g., to protect the components within the enclosure 104 from external environment. For example, the junction between the enclosure 104 and cover 140, as well as various ports within enclosure 104, are hermetically sealed. However, in another example, the apparatus 100 may not be hermetically sealed.

As illustrated in FIGS. 1A and 1B, an input signal 106 is received by the apparatus 100 at an input port 105 of the enclosure 104. The input signal 106 may be received from a signal source, such as a backend circuit. The apparatus 100 provides an output signal 108 through an output port 109 of the enclosure 104, e.g., to a transmit antenna. FIG. 1D illustrates a cross-sectional view of the input port 104 and the output port 109. In an example, the input port 105 and the output port 109 are hermetically sealed, such that openings for any cabling extending through these ports are sealed hermetically.

As discussed above, in an example, the input signal 106 of the apparatus 100 is received from a backend circuit, and the output signal 108 of the apparatus 100 is provided to a transmit antenna, in an example, although the apparatus 100 may be used in another signal routing and/or signal processing application as well. In an example, each of the input signal 106 and the output signal 108 comprises a corresponding radio frequency (RF) signal.

As described above, the apparatus 100 includes an input transmission line 111 and an output transmission line 115 within the enclosure 104. In an example, the transmission lines 111 and 115 (as well as other transmission lines) can be microstrips. As will be appreciated in light of this disclosure, reference to microstrips is also intended to include other types of transmission lines, such as strip lines, or through lines, or and/or RF input or output pins, for example. To this end, the use of a specific type of transmission line (such as microstrip) is not intended to limit the present description to that specific type of transmission line. Rather, the techniques provided herein can benefit any type of transmission lines, whether those transmission lines be microstrips, or strip lines, through lines, RF input or output pins, and/or any other type of transmission lines. The input microstrip 111 is a microstrip transmission line comprising a conductive line 112 (also referred to as a conductor 112) on a substrate 113 comprising dielectric material. A ground plane comprising conductive material is below the substrate 113, although not visible in the illustrations of FIGS. 1A-1F. The input microstrip 111 (such as the conductor 112) receives the input signal 106 through the input port 105, and provides the input signal 106 to the die 110.

The integrated circuit die 110a receives the input signal 106 from the input microstrip 111, and processes the input signal 106 to generate a corresponding output. The output of the integrated circuit die 110a is received by the integrated circuit die 110b. The integrated circuit die 110b generates the output signal 108, which is provided to the output port 108 of the enclosure 104 through the output microstrip 115 (such as the conductor 116).

In an example, the integrated circuit die 110a and 110b are any type of integrated circuit die for processing the input signal 106, and generating the output signal 108. In an example where the input and/or output signals 106, 108, respectively, are RF signals, the integrated circuit die 110a, 110b may be monolithic microwave integrated circuit (MMIC) die.

In an example, the integrated circuit die 110a may include a driver amplifier, an attenuator, a phase shifter, and/or another integrated circuit die for processing RF signals to be provided to a transmit antenna. In an example, the integrated circuit die 110b may include a power amplifier, such as a high power amplifier (HPA), for amplifying a RF signal, prior to transmission of the RF signal to a transmit antenna. Thus, in the example of FIGS. 1A-1F, the output signal 108 of the apparatus 100 is provided to the transmit antenna.

The output microstrip 115 is a microstrip transmission line comprising a conductive line 116 (also referred to as a conductor 116) on a substrate 117 comprising dielectric material. A ground plane comprising conductive material is below the substrate 117, although not visible in the illustrations of FIGS. 1A-1F. The output microstrip 117 receives the output signal 108 from the integrated circuit die 110b, and provides the output signal 108 to the output port 109.

Lengths of the enclosure 104 and various components therewithin are measured along the X axis in FIGS. 1A-1F. A length of the input microstrip 111 (e.g., measured in the direction parallel to a length of the enclosure 104 along the X axis) is Lina, as illustrated in FIG. 1B. A length of the output microstrip 115 is Louta, as illustrated in FIG. 1B. A length of the die 110a is La, and a length of the die 110b is Lb. An overall length of the enclosure 104 is L1, as illustrated in FIGS. 1E and 1F.

In an example, the enclosure 104 has dimensions such that the enclosure 104 is able to accommodate one or more integrated circuit die of varying lengths. For example, a length of the enclosure 104 from an end of the input microstrip 111 (e.g., the end facing the input port 105) to an end of the output microstrip 115 (e.g., the end facing the output port 109) is L, see FIG. 1B. The input microstrip 111, the integrated circuit die 110a and 110b, and the output microstrip 115 have to be accommodated within this length L. Note that this L is fixed and is based on the overall length L1 of the enclosure 104. The length L1 of the enclosure 104 and the corresponding length L of FIG. 1B cannot be changed once the enclosure 104 is designed and/or manufactured. Also note that the integrated circuit die 110a and 110b have fixed lengths of La and Lb, respectively, as well.

In an example, the input microstrip 111, the integrated circuit die 110a and 110b, and the output microstrip 115 have to be “perfectly” accommodated within the length L, where the phrase “perfectly” implies that there may not be any unplanned or random gap between a microstrip and an integrated circuit die, or between two integrated circuit die. Because the lengths L, La, and Lb are fixed, for such accommodation of the components within the length L, the lengths Lina and/or Louta of the input microstrip 111 and the output microstrip 115, respectively, may be configurable or variable. Thus, the lengths Lina and/or Louta may be made larger or smaller, depending on the lengths L, La, and Lb.

For example, if two relatively large sized die having relatively large lengths are to be accommodated within the enclosure 104, the lengths Lina and/or Louta may be made correspondingly smaller. On the other hand, if two relatively smaller sized die (or a single die) having relatively small lengths are to be accommodated within the enclosure 104, the lengths Lina and/or Louta may be made correspondingly larger. Thus, the lengths Lina and/or Louta of the input microstrip 111 and the output microstrip 115, respectively, may be designed according to the lengths La and Lb of the integrated circuit die 110a, 110b, respectively, as the length L of the enclosure 104 is fixed.

Note that in FIGS. 1A-1F, the output signal 108 of the apparatus 100 is provided to the transmit antenna. For example, the integrated circuit die 110b (which may be a power amplifier) amplifies an RF signal, and the amplifier RF output signal 108 is provided to the transmit antenna for emitting by the transmit antenna. In such an example, it may be desirable to shorten a length of transmission line traversed by the output signal 108, such that the power of the RF output signal 108 is not lost due to transmission over a relatively long output microstrip 115. Accordingly, in such an example, the length Louta of the output microstrip 115 is maintained relatively short (e.g., as short as possible in one example), and the length Lina of the input microstrip 111 is varied or configured, for purposes of accommodating the microstrips 111, 115 and integrated circuit die 110a, 110b within the length L. Hence, as illustrated in FIG. 1B, the length Lina is greater than the length Louta, e.g., by at least 2%, or at least 5%, or at least 7%, or at least 10%, or at least 15%, or at least 20%, for example.

The apparatus 100 further includes one or more passive elements 132, such as capacitors, inductors, and/or resistors, within the enclosure 104. The passive elements 132 may be disposed on any one or both sides of the integrated circuit die 110a, 110b. Locations, numbers, and/or shapes of the passive elements 132 illustrated in FIGS. 1A-1B are mere examples.

One or more feed through conductors 124 extend from outside to within the enclosure 124. Locations, numbers, and/or shapes of the feed through conductors 124 illustrated in FIGS. 1A-1F are mere examples. The feed through conductors 124 provide various signaling to the enclosure 104 from outside. In an example, one or more of the conductors 124 transmit direct current (DC) signals providing biasing and power to one or more components within the enclosure 104. In another example, one or more of the conductors 124 provide control signals, clock signals, and/or other types of signals to one or more components within the enclosure 104.

The apparatus 100 comprises, within the enclosure 104, a layer of dielectric material 136a and conductive traces 138a thereon, where the conductive traces 138a route various signals of the apparatus 100. Similarly, the apparatus 100 further comprises, within the enclosure 104, another layer of dielectric material 136b and conductive traces 138b thereon, where the conductive traces 138b route various signals of the apparatus 100

In one embodiment, a width of the integrated circuit die 110a is Wa and a width of the integrated circuit die 110b is Wb, as illustrated in FIG. 1B, where various widths described herein are measured in the direction of Y axis, and perpendicular to a direction in which the lengths are measured. An overall width of the enclosure 104 is W1, as illustrated in FIGS. 1E and 1F. In an example, to accommodate the widths Wa and Wb, respectively, of the integrated circuit die 110a and 110b within the width W1 of the enclosure 104, the widths of the layers of dielectric material 136a, 136b may be adjusted. For example, for larger widths Wa and/or Wb, the widths of the layers of dielectric material 136a, 136b may be adjusted to be relatively smaller; and for smaller widths Wa and/or Wb, the widths of the layers of dielectric material 136a, 136b may be adjusted to be relatively larger.

In one embodiment, the apparatus 100 comprises one or more heat spreaders 122 within the enclosure 104. The heat spreaders 122 comprise thermally conductive material, such as one or more metals and/or alloys thereof. The heat spreaders 122 spreads heat from the integrated circuit die 110a, 110b and/or from the passive components 132 to the enclosure 104, and the heat spreaders 122 and/or the enclosure 104 dissipate the heat and facilitate cooling of the integrated circuit die 110a, 110b and/or the passive components 132.

In one embodiment, the apparatus 100 is affixed to another apparatus using bolts or screws passing through openings 130 within the apparatus, although other ways to affix the apparatus (such as soldering, using adhesive, and so on) may also be used. In the example of FIGS. 1A-1F, the openings 130 are in four corners of the apparatus 100, and mounting screws or bolts may be used to mount the apparatus 100. Locations and/or numbers of the openings 130 illustrated in FIGS. 1A-1F are mere examples.

In one embodiment, the apparatus 100 also includes one or more ground lugs 128, which may be used to electrically ground the apparatus 100. As described above, in an example, the enclosure 104 comprises conductive material (such as aluminum), and the enclosure 104 may also facilitate in grounding. The electrical components within the enclosure 104 (such as the integrated circuit die 110a, 110b), and the enclosure 104, may be coupled to external ground connection through the conductive ground lug 128. A location and/or a number of the ground lug(s) 128 illustrated in FIGS. 1A-1F are mere examples.

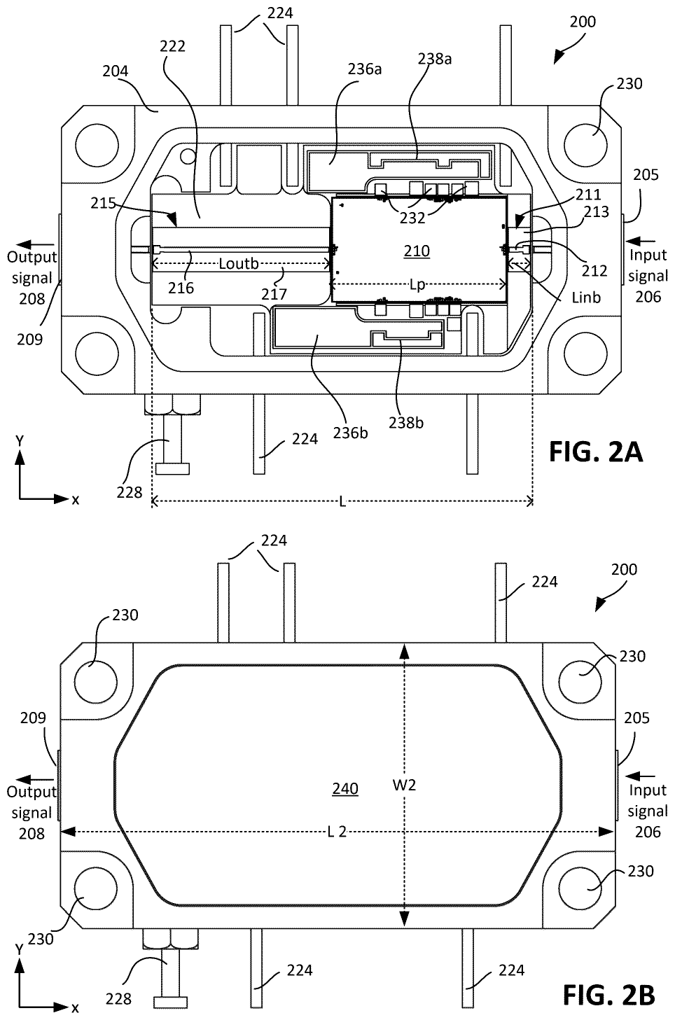

FIGS. 2A and 2B schematically illustrate various views of another apparatus 200 comprising (i) an enclosure 204, (ii) an input microstrip 211 within the enclosure 204, (iii) an output microstrip 215 within the enclosure 204, and (iv) one or more integrated circuit die 210 within the enclosure 204 and laterally between the input microstrip 211 and the output microstrip 215, in accordance with an embodiment of the present disclosure.

Specifically, FIG. 2A illustrates a plan view of the apparatus 200, without a cover 240 of the enclosure 204 (such that components within the enclosure 204 are visible). FIG. 2B illustrates a plan view of the apparatus 200, with the cover 240 of the enclosure 204 (such that one or more components within the apparatus 200, which were visible in FIG. 2A, are not visible in FIG. 2B).

Similar to the apparatus 100, the apparatus 200 of FIGS. 2A-2B includes the enclosure 204, which is a housing for the components there within. In an example, the body of the enclosure 204 comprises conductive material, such as one or more metals and/or alloys thereof (e.g., aluminum). In an example, the enclosure 204 and cover 240 are hermetically sealed, e.g., to protect the components within the enclosure 204 from external environment.

An input signal 206 is received by the apparatus 200 at an input port 205 of the enclosure 204. The input signal 206 may be received from a signal source, such as a receive antenna. The apparatus 200 provides an output signal 208 through an output port 209 of the enclosure 204, e.g., to a backend RF circuit. In an example, the input port 205 and the output port 209 are hermetically sealed, such that openings of these ports through which any cabling extends are sealed hermetically. In an example, the input signal 206 and the output signal 208 comprise RF signals.

As described above, the apparatus 200 includes an input microstrip 211 and an output microstrip 215 within the enclosure 204. The input microstrip 211 is a microstrip transmission line comprising a conductive line 212 (also referred to as a conductor 212) on a substrate 213 comprising dielectric material. A ground plane comprising conductive material is below the substrate 213, although not visible in the illustrations of FIG. 2A. The input microstrip 211 receives the input signal 206 from the input port 205, and provides the input signal 206 to the integrated circuit die 210.

The apparatus 200 includes a single integrated circuit die 210 in the example of FIG. 2A, although the apparatus 200 may include two, or three, or a higher number of integrated circuit die. The integrated circuit die 210 receives the input signal 206 from the input microstrip 211, and processes the input signal 206 to generate the output signal 208. In an example, the integrated circuit die 210 comprises any type of integrated circuit die for processing the input signal 206, and generating the output signal 208. In an example where the input and output signals 206 and 208, respectively, are RF signals, the integrated circuit die 210 may be a MMIC die. For example, the integrated circuit die 210 may operate at RF frequencies. In an example where the input signal 206 is received from a receive antenna, the integrated circuit die 210 may include a low noise amplifier (LNA), although another type of die may also be used in other examples.

The output microstrip 215 is a microstrip transmission line comprising a conductive line 216 (also referred to as a conductor 216) on a substrate 217 comprising dielectric material. A ground plane comprising conductive material is below the substrate 217, although not visible in the illustrations of FIG. 2A. The output microstrip 217 receives the output signal 208 from the integrated circuit die 210, and provides the output signal 208 to the output port 209.

Lengths of the apparatus 200 and various components therewithin are measured along the X axis in FIGS. 2A-2B; and widths of the apparatus 200 and various components therewithin are measured along the Y axis in FIGS. 2A-2B.

In one embodiment, the enclosure 204 of FIGS. 2A-2B have substantially same dimensions as the enclosure 104 of FIGS. 1A-1E. For example, an overall length of the enclosure 204 is L2 and an overall width of the enclosure 204 is W2, as illustrated in FIG. 2B. In one embodiment, length L1 of the enclosure 104 (see FIGS. 1E and 1F) and length L2 of the enclosure 204 (see FIG. 2B) are substantially the same, such as within 1%, or within 2%, or within 3%, or within 4%, or within 5% of each other, for example. In one embodiment, width W1 of the enclosure 104 and width W2 of the enclosure 204 are substantially the same, such as within 1%, or within 2%, or within 3%, or within 4%, or within 5% of each other. Similarly, a height of the two enclosures 104, 204 (e.g., where the height is measured in the Z axis direction in FIGS. 1A-2B) are also substantially the same, e.g., within 1%, or within 2%, or within 3%, or within 4%, or within 5% of each other. For example, any minor difference between the lengths L1 and L2, or between widths W1 and W2, or between the heights of the enclosures 104 and 204 may be due to unintended consequences of variability or randomness in the manufacturing process to manufacture these enclosures.

A length of the input microstrip 211 is Linb, as illustrated in FIG. 2A. A length of the output microstrip 215 is Loutb, as illustrated in FIG. 2B. A length of the die 210 is Lp.

In an example, the enclosure 204 has dimensions substantially similar to the dimensions of the enclosure 104. For example, each of the enclosures 104, 204 is sized to include integrated circuit die 110a, 110b, or integrated circuit die 210. Accordingly, the enclosure 204 is able to accommodate one or more integrated circuit die of varying lengths, such as the die 110a and 110b in FIGS. 1A-1F, and the die 210 in FIGS. 2A-2B. For example, a length of the enclosure 204 from an end of the input microstrip 211 (e.g., the end facing the input port 205) to an end of the output microstrip 215 (e.g., the end facing the output port 209) is also L, see FIGS. 1B and 2A. The length L in FIGS. 1B and 2A are substantially the same, e.g., within 1%, or within 2%, or within 3%, or within 4%, or within 5% of each other. The input microstrip 211, the integrated circuit die 210, and the output microstrip 215 have to be accommodated within this length L. Note that this L is fixed. Also note that the integrated circuit die 210 has fixed length of Lp.

Accordingly, the input microstrip 211, the integrated circuit die 210, and the output microstrip 215 have to be accommodated within this length L. Because the lengths L and Lp are fixed, for such accommodation of the components within the length L, the lengths Linb and/or Loutb of the input microstrip 211 and the output microstrip 215, respectively, may be configurable. Thus, the lengths Linb and/or Loutb may be made larger or smaller, depending on the lengths L and Lp.

For example, if a relatively large sized die having relatively large length and/or multiple integrated circuit die are to be accommodated within the enclosure 204, the lengths Linb and/or Loutb may be made correspondingly smaller. On the other hand, if a relatively smaller sized die having a relatively small length is to be accommodated within the enclosure 204, the lengths Linb and/or Loutb may be made correspondingly larger. Thus, the lengths Linb and/or Loutb of the input microstrip 211 and the output microstrip 215, respectively, may be designed according to the length Lp of the integrated circuit die 210, as the length L of the enclosure 204 is fixed, in an example.

Note that in FIGS. 2A-2B, the input signal 208 of the apparatus 200 is received from a receive antenna. For example, the integrated circuit die 210 (which may be a low noise amplifier (LNA)) amplifies an RF signal received at the receive antenna. In such an example, it may be desirable to shorten a length of transmission line traversed by the input signal 206 prior to reaching the integrated circuit die 210, such that the power of the RF input signal 206 is not lost due to transmission over a relatively long input microstrip 215. Accordingly, in an example, the length Linb of the input microstrip 213 is maintained relatively short (e.g., as short as possible in one example), and the length Loutb of the output microstrip 215 is varied or configured, for purposes of accommodating the microstrips 211, 215 and integrated circuit die 210 within the length L. Hence, as illustrated in FIG. 2A, the length Loutb is greater than the length Linb, e.g., by at least 2%, or at least 5%, or at least 7%, or at least 10%, or at least 15%, or at least 20%, for example.

Similar to the apparatus 100 of FIGS. 1A-1F, the apparatus 200 of FIGS. 2A-2B further includes one or more passive elements 232, such as capacitors, inductors, and/or resistors, one or more feed through conductors 224 extending from outside to within the enclosure 224, a layer of dielectric material 236a and conductive traces 238a thereon, another layer of dielectric material 236b and conductive traces 238b thereon, one or more heat spreaders 222, openings 230, and/or one or more ground lugs 228, and these components will be apparent from the description of the corresponding components with respect to the apparatus 100 of FIGS. 1A-1E.

In one embodiment, in addition to the same dimensions of the two enclosures 104 and 204 (e.g., within a tolerance level of 1% or 2%, for example), one or more features of the two enclosures 104 and 204 may also match (e.g., within a tolerance level of 1% or 2%, for example). For example, the apparatus 200 includes the one or more ground lugs 228, whereas the apparatus 100 includes the one or more ground lugs 128. In one embodiment, a size of the ground lug 128 and/or a location of the ground lug 128 with respect to the enclosure 104 are respectively within 2% of a size of the ground lug 228 and/or a location of the ground lug 228 with respect to the enclosure 204.

Similarly, the apparatus 200 includes one or more feed-through conductors 224, whereas the apparatus 100 includes one or more feed-through conductors 124. In one embodiment, a size of a feed-through conductor 124 and/or a location of the feed-through conductor 124 with respect to the enclosure 104 are respectively within 2% of a size of the corresponding feed through conductor 224 and/or a location of the feed-through conductor 224 with respect to the enclosure 204.

Similarly, the apparatus 200 includes the input/output (I/O) port 205 and the I/O port 209, whereas the apparatus 100 includes the I/O ports 105 and 109. In one embodiment, a size of the I/O port 105 and/or a location of the I/O port 105 with respect to the enclosure 104 are respectively within 2% of a size of the I/O port 209 and/or a location of the I/O port 209 with respect to the enclosure 204. Similarly, in one embodiment, a size of the I/O port 109 and/or a location of the I/O port 109 are respectively within 2% of a size of the I/O port 205 and/or a location of the I/O port 205 with respect to the enclosure 204.

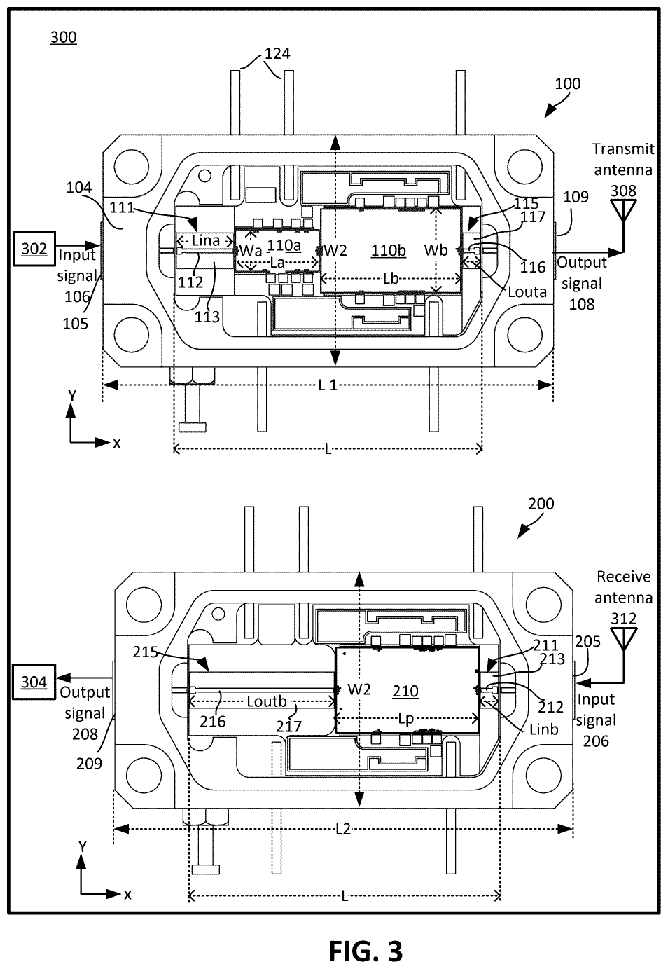

FIG. 3 illustrates a system 300 including the apparatus 100 of FIGS. 1A-1F and the apparatus 200 of FIGS. 2A-2B, in accordance with an embodiment of the present disclosure. For example, in the system 300, the apparatus 100 receives the RF input signal 106 from a RF signal circuit 302. The apparatus 100, such as the integrated circuit die 110a, 110b, processes (such as amplifies) the input RF signal 106 and generates RF output signal 108 that is provided to a transmit antenna 308 for transmission.

In the system 300, the apparatus 200 receives the RF input signal 206 from a receive antenna 312. The apparatus 200, such as the integrated circuit die 210, processes (such as amplifies) the input RF signal 206 and generates RF output signal 208 that is provided to a backend RF processing circuit 304.

As described above, the enclosures 104 and 204 have substantially the same dimensions. For example, the length L1 of the enclosure 104 and the length L2 of the enclosure 204 are within 1%, or within 2%, or within 3%, or within 4%, or within 5% of each other. Similarly, the width W1 of the enclosure 104 and the width W2 of the enclosure 204 are within 1%, or within 2%, or within 3%, or within 4%, or within 5% of each other. Similarly, a height of the two enclosures 104, 204 (e.g., where the height is measured in the Z axis direction in FIGS. 1A-2B) are also substantially the same, e.g., within 1%, or within 2%, or within 3%, or within 4%, or within 5% of each other. For example, any minor difference between the lengths L1 and L2, or between widths W1 and W2, or between the heights of the enclosures 104 and 204 may be due to unintended consequences of variability or randomness in the manufacturing process to manufacture these enclosures.

Furthermore, the length L in both the apparatus 100 and 200 represents a length between an end of an input microstrip facing the input port and an end of an output microstrip facing the output port (e.g., see FIGS. 1B and 2A). The length L in both the enclosures 104 and 204 are substantially the same, such as within 1%, or within 2%, or within 3%, or within 4%, or within 5% of each other.

Thus, multiple instances of the enclosures 104 or 204 are manufactured, each having substantially the same dimensions, thereby making the design and/or production process of these enclosures easy and cost effective. Subsequent to the production, the same dimensioned enclosures can be used for different purposes, such as may be used as the apparatus 100 to accommodate the integrated circuit die 110a, 110b, or the apparatus 200 to accommodate the integrated circuit die 210. For example, the lengths of the input and/or output microstrips within an enclosure may be varied, to accommodate integrated circuit die of varying number and/or length within the enclosure. Thus, while the enclosure 104 having the dimensions of L1 and W1 is able to accommodate two integrated circuit die 110a, 110b (e.g., having lengths La and Lb), the enclosure 204 having substantially the same dimensions is able to accommodate one integrated circuit die 210 (e.g., having length Lp).

Also, for reasons described above, one of the input or output microstrips within an enclosure, which is closer to an antenna, is made shorter than the other of the input or output microstrips. Accordingly, in the apparatus 100, the length Lina of the input microstrip 111 is greater than the length Louta of the output microstrip 115, e.g., by at least 2%, or at least 5%, or at least 7%, or at least 10%, or at least 15%, or at least 20%, for example. Similarly, in the apparatus 200, the length Loutb of the output microstrip 215 is greater than the length Linb of the input microstrip 211, e.g., by at least 2%, or at least 5%, or at least 7%, or at least 10%, or at least 15%, or at least 20%, for example.

Similarly, the lengths Loutb and Lina may differ by at least 2%, or at least 5%, or at least 7%, or at least 10%, or at least 15%, or at least 20%, for example. Similarly, the lengths Loutb and Louta may differ by at least 2%, or at least 5%, or at least 7%, or at least 10%, or at least 15%, or at least 20%, for example. Similarly, the lengths Linb and Louta may differ by at least 2%, or at least 5%, or at least 7%, or at least 10%, or at least 15%, or at least 20%, for example. Similarly, the lengths Linb and Lina may differ by at least 2%, or at least 5%, or at least 7%, or at least 10%, or at least 15%, or at least 20%, for example.

Similarly, a sum of the lengths of the one or more integrated circuit die 110a, 110b within the enclosure 104 is (La+Lb), and a sum of the lengths of the one or more integrated circuit die 210 within the enclosure 204 is Lp, where (La+Lb) and Lp may differ by at least 2%, or at least 5%, or at least 7%, or at least 10%, or at least 15%, or at least 20%, for example.

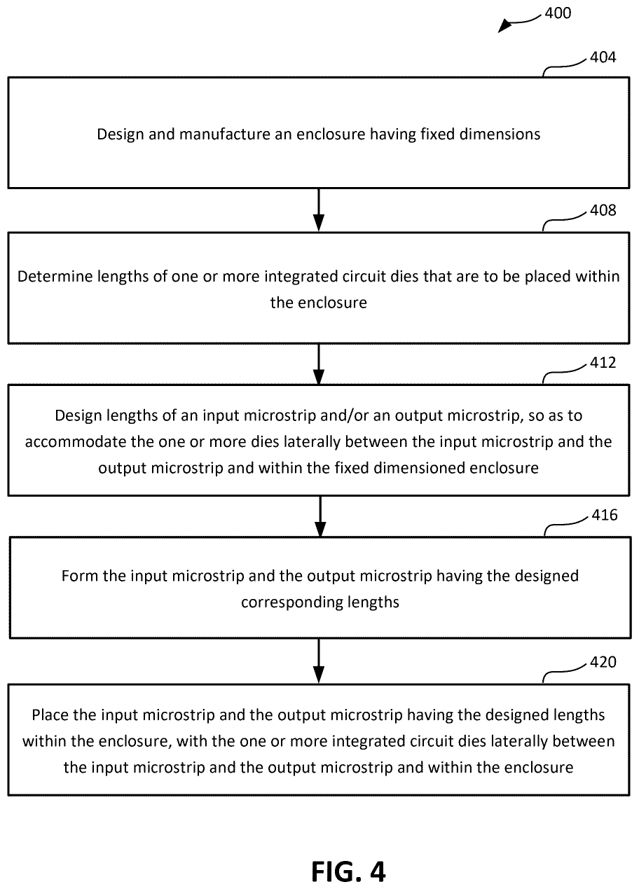

FIG. 4 illustrates a flowchart depicting a method 400 of designing and forming any of the apparatus 100 or 200 of FIGS. 1A-2B, in accordance with an embodiment of the present disclosure.

At 404 of method 400, an enclosure (such as any of the enclosures 100 or 200) having fixed dimensions is designed and manufactured. The method 400 then proceeds from 404 to 408. At 408, lengths of one or more integrated circuit die that are to be placed within the enclosure are determined. For example, the one or more die 110a and 110b to be placed within the enclosure 104 has lengths of La and Lb, respectively. Similarly, the one or more die 210 to be placed within the enclosure 204 has a length of Lp.

The method 400 then proceeds from 408 to 412. At 412, lengths of an input microstrip and/or an output microstrip are designed, so as to accommodate the one or more die laterally between the input microstrip and the output microstrip and within the fixed dimensioned enclosure. For example, in FIGS. 1A-1F, the lengths of the input microstrip 111 and the output microstrip 115 are designed to be Lina and Louta, respectively, so as to accommodate the one or more die 110a, 110b laterally between the input microstrip 111 and the output microstrip 115 and within the fixed dimensioned enclosure 104. Similarly, in FIGS. 2A-2B, the lengths of the input microstrip 211 and the output microstrip 215 are designed to be Linb and Loutb, respectively, so as to accommodate the one or more die 210 laterally between the input microstrip 211 and the output microstrip 215 and within the fixed dimensioned enclosure 204.

The method 400 then proceeds from 412 to 416. At 416, the input microstrip and the output microstrip having the designed corresponding lengths are formed, e.g., using techniques for forming microstrips.

The method 400 then proceeds from 416 to 420. At 420, the input microstrip and the output microstrip having the designed lengths are placed within the enclosure, with the one or more integrated circuit die placed laterally between the input microstrip and the output microstrip and within the enclosure, e.g., as illustrated in FIGS. 1A-2B.

Note that the processes in method 400 are shown in a particular order for ease of description. However, one or more of the processes may be performed in a different order or may not be performed at all (and thus be optional), in accordance with some embodiments. For example, the enclosure may be manufactured at process 404, or at any time prior to process 420. Numerous variations on method 400 and the techniques described herein will be apparent in light of this disclosure.

### Further Examples

The following examples pertain to further examples, from which numerous permutations and configurations will be apparent.
Example 1. A system comprising: a first enclosure comprising conductive material, a first input transmission line within the first enclosure, a first output transmission line within the first enclosure, and first one or more die within the first enclosure and laterally between the first input transmission line and the first output transmission line; and a second enclosure comprising conductive material, a second input transmission line within the second enclosure, a second output transmission line within the second enclosure, and second one or more die within the second enclosure and laterally between the second input transmission line and the second output transmission line; wherein one or more dimensions of the first enclosure is within 2% of corresponding one or more dimensions of the second enclosure; and wherein a length of the first input transmission line differs from a length of the second input transmission line by at least 5%, wherein the length of the first input transmission line is measured in a direction parallel to a length of the first enclosure, and wherein the length of the second input transmission line is measured in a direction parallel to a length of the second enclosure.
Example 2. The system of example 1, wherein: the first input transmission line has a first end facing the first one or more die and an opposing second end, and the first output transmission line has a third end facing the first one or more die and an opposing fourth end; a first distance is between the second end of the first input transmission line and the fourth end of the first output transmission line; the second input transmission line has a fifth end facing the second one or more die and an opposing sixth end, and the second output transmission line has a seventh end facing the second one or more die and an opposing eighth end; a second distance is between the sixth end of the second input transmission line and the eighth end of the second output transmission line; and the first distance differs from the second distance by at most 1%.
Example 3. The system of any one of examples 1-2, wherein: a sum of length of the first one or more die differs from a sum of length of the second one or more die by at least 5%.
Example 4. The system of any one of examples 1-3, wherein one or more of: a length of the first input transmission line differs from a length of the second output transmission line by at least 5%; a length of the first output transmission line differs from the length of the second output transmission line by at least 5%; and/or the length of the first output transmission line differs from a length of the second input transmission line by at least 5%.
Example 5. The system of any one of examples 1-4, further comprising: a first input/output port within the first enclosure; and a second input/output port within the second enclosure; wherein a size of the first input/output port and a location of the first input/output port with respect to the first enclosure are respectively within 2% of a size of the second input/output port and a location of the second input/output port with respect to the second enclosure.
Example 6. The system of any one of examples 1-5, further comprising: a first ground lug in contact with the first enclosure; and a second ground lug in contact with the second enclosure, wherein a size of the first ground lug and a location of the first ground lug with respect to the first enclosure are respectively within 2% of a size of the second ground lug and a location of the second ground lug with respect to the second enclosure.
Example 7. The system of any one of examples 1-6, further comprising: a first feed through conductor extending within the first enclosure; and a second feed through conductor extending within the second enclosure, wherein a size of the first feed through conductor and a location of the first feed through conductor with respect to the first enclosure are respectively within 2% of a size of the second feed through conductor and a location of the second feed through conductor with respect to the second enclosure.
Example 8. The system of any one of examples 1-7, further comprising: a transmit antenna, wherein a radio frequency signal output by the first output transmission line within the first enclosure is provided to the transmit antenna, wherein a length of the first output transmission line is smaller than a length of the first input transmission line by at least 5%.
Example 9. The system of any one of examples 1-8, further comprising: a receive antenna, wherein a radio frequency signal received by the receive antenna is provided to the second input transmission line within the second enclosure, wherein a length of the second input transmission line is smaller than a length of the second output transmission line by at least 5%.
Example 10. The system of any one of examples 1-9, wherein: the lengths of the first input transmission line and/or the first output transmission line are adjustable, so as to accommodate the first one or more die having a corresponding fixed length laterally between the first input transmission line and the first output transmission line within the first enclosure also having a corresponding fixed length.
Example 11. The system of any one of examples 1-10, wherein: the lengths of the second input transmission line and/or the second output transmission line are adjustable, so as to accommodate the second one or more die having a corresponding fixed length laterally between the second input transmission line and the second output transmission line within the second enclosure also having a corresponding fixed length.
Example 12. The system of any one of examples 1-11, wherein each of the first enclosure and the second enclosure is hermetically sealed, and wherein each of the first enclosure and the second enclosure comprises aluminum.
Example 13. A method comprising: receiving an enclosure comprising conductive material and having a fixed length; determining lengths of one or more die that are to be placed within the enclosure; designing lengths of an input transmission line and an output transmission line, so as to accommodate the one or more die laterally between the input transmission line and the output transmission line and within the enclosure having the fixed length; forming the input transmission line and the output transmission line having the designed corresponding lengths; and placing the input transmission line and the output transmission line having the designed lengths within the enclosure, with the one or more integrated circuit die laterally between the input transmission line and the output transmission line and within the enclosure.
Example 14. The method of example 13, wherein: the designed length of the input transmission line differs from the designed length of the output transmission line by at least 5%.
Example 15. The method of any one of examples 13-14, further comprising: connecting the output transmission line to a transmit antenna configured to emit a radio frequency signal, wherein the designed length of the input transmission line is greater than the designed length of the output transmission line by at least 5%.
Example 16. The method of any one of examples 13-15, further comprising: connecting the input transmission line to a receive antenna, such that the input transmission line is configured to receive radio frequency signals received by the receive antenna, wherein the designed length of the output transmission line is greater than the designed length of the input transmission line by at least 5%.
Example 17. The method of any one of examples 13-16, wherein the one or more die comprises a low noise amplifier or a high power amplifier.
Example 18. The method of any one of examples 13-17, wherein the one or more die comprises a monolithic microwave integrated circuit (MMIC) die.
Example 19. A system comprising: a first enclosure, a first input transmission line within the first enclosure, a first output transmission line within the first enclosure, and a first number of die within the first enclosure and laterally between the first input transmission line and the first output transmission line; and a second enclosure, a second input transmission line within the second enclosure, a second output transmission line within the second enclosure, and a second number of die within the second enclosure and laterally between the second input transmission line and the second output transmission line, wherein the first and second numbers differ by at least one; wherein one or more dimensions of the first enclosure is within 2% of corresponding one or more dimensions of the second enclosure.
Example 20. The system of example 19, wherein: a sum of length of the first number of die within the first enclosure differs from a sum of length of the second number of die within the second enclosure by at least 5%; and a sum of length of the first input and first output transmission lines differs from a length of a sum of length of the second input and second output transmission lines by at least 5%.
Example 21. An apparatus comprising: an enclosure comprising conductive material; an input transmission line within the enclosure; an output transmission line within the enclosure; and one or more integrated circuit die within the enclosure and laterally between the input transmission line and the output transmission line; wherein a length of the input transmission line differs from a length of the output transmission line by at least 10%.
Example 22. The apparatus of example 21, wherein the enclosure comprises: an input port configured to receive an input radio frequency signal; and an output port configured to output an output radio frequency signal, wherein the input transmission line is coupled between the input port and the one or more integrated circuit die; and wherein the output transmission line is coupled between the output port and the one or more integrated circuit die.
Example 23. The apparatus of any one of examples 21-22, wherein: a radio frequency signal output by the output transmission line is provided to the transmit antenna; and a length of the output transmission line is smaller than a length of the input transmission line by at least 5%.
Example 24. The apparatus of any one of examples 21-23, wherein: a radio frequency signal output by a receive antenna is received by the input transmission line; and wherein a length of the input transmission line is smaller than a length of the output transmission line by at least 5%.

Numerous specific details have been set forth herein to provide a thorough understanding of the examples. It will be understood, however, that other examples may be practiced without these specific details, or otherwise with a different set of details. It will be further appreciated that the specific structural and functional details disclosed herein are representative of examples and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims. Furthermore, examples described herein may include other elements and components not specifically described, such as electrical connections, signal transmitters and receivers, processors, or other suitable components for operation of the antenna system 100.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and examples have been described herein. The features, aspects, and examples are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A system comprising:
a first enclosure comprising conductive material, a first input transmission line within the first enclosure, a first output transmission line within the first enclosure, and first one or more die within the first enclosure and laterally between the first input transmission line and the first output transmission line; and
a second enclosure comprising conductive material, a second input transmission line within the second enclosure, a second output transmission line within the second enclosure, and second one or more die within the second enclosure and laterally between the second input transmission line and the second output transmission line;
wherein one or more dimensions of the first enclosure is within 2% of corresponding one or more dimensions of the second enclosure; and
wherein a length of the first input transmission line differs from a length of the second input transmission line by at least 5%, wherein the length of the first input transmission line is measured in a direction parallel to a length of the first enclosure, and wherein the length of the second input transmission line is measured in a direction parallel to a length of the second enclosure.

2. The system of claim 1, wherein:
the first input transmission line has a first end facing the first one or more die and an opposing second end, and the first output transmission line has a third end facing the first one or more die and an opposing fourth end;
a first distance is between the second end of the first input transmission line and the fourth end of the first output transmission line;
the second input transmission line has a fifth end facing the second one or more die and an opposing sixth end, and the second output transmission line has a seventh end facing the second one or more die and an opposing eighth end;
a second distance is between the sixth end of the second input transmission line and the eighth end of the second output transmission line; and
the first distance differs from the second distance by at most 1%.

3. The system of claim 1, wherein:
a sum of length of the first one or more die differs from a sum of length of the second one or more die by at least 5%.

4. The system of claim 1, wherein one or more of:
a length of the first input transmission line differs from a length of the second output transmission line by at least 5%;
a length of the first output transmission line differs from the length of the second output transmission line by at least 5%; and/or
the length of the first output transmission line differs from a length of the second input transmission line by at least 5%.

5. The system of claim 1, further comprising:
a first input/output port within the first enclosure; and
a second input/output port within the second enclosure;
wherein a size of the first input/output port and a location of the first input/output port with respect to the first enclosure are respectively within 2% of a size of the second input/output port and a location of the second input/output port with respect to the second enclosure.

6. The system of claim 1, further comprising:
a first ground lug in contact with the first enclosure; and
a second ground lug in contact with the second enclosure,
wherein a size of the first ground lug and a location of the first ground lug with respect to the first enclosure are respectively within 2% of a size of the second ground lug and a location of the second ground lug with respect to the second enclosure.

7. The system of claim 1, further comprising:
a first feed through conductor extending within the first enclosure; and
a second feed through conductor extending within the second enclosure,
wherein a size of the first feed through conductor and a location of the first feed through conductor with respect to the first enclosure are respectively within 2% of a size of the second feed through conductor and a location of the second feed through conductor with respect to the second enclosure.

8. The system of claim 1, further comprising:
a transmit antenna, wherein a radio frequency signal output by the first output transmission line within the first enclosure is provided to the transmit antenna,
wherein a length of the first output transmission line is smaller than a length of the first input transmission line by at least 5%.

9. The system of claim 1, further comprising:
a receive antenna, wherein a radio frequency signal received by the receive antenna is provided to the second input transmission line within the second enclosure,
wherein a length of the second input transmission line is smaller than a length of the second output transmission line by at least 5%.

10. The system of claim 1, wherein:
the lengths of the first input transmission line and/or the first output transmission line are adjustable, so as to accommodate the first one or more die having a corresponding fixed length laterally between the first input transmission line and the first output transmission line within the first enclosure also having a corresponding fixed length.

11. The system of claim 1, wherein:
the lengths of the second input transmission line and/or the second output transmission line are adjustable, so as to accommodate the second one or more die having a corresponding fixed length laterally between the second input transmission line and the second output transmission line within the second enclosure also having a corresponding fixed length.

12. The system of claim 1, wherein each of the first enclosure and the second enclosure is hermetically sealed, and wherein each of the first enclosure and the second enclosure comprises aluminum.

13. A method comprising:
receiving an enclosure comprising conductive material and having a fixed length;
determining lengths of one or more die that are to be placed within the enclosure;
designing lengths of an input transmission line and an output transmission line, so as to accommodate the one or more die laterally between the input transmission line and the output transmission line and within the enclosure having the fixed length;
forming the input transmission line and the output transmission line having the designed corresponding lengths; and
placing the input transmission line and the output transmission line having the designed lengths within the enclosure, with the one or more integrated circuit die laterally between the input transmission line and the output transmission line and within the enclosure.

14. The method of claim 13, wherein:
the designed length of the input transmission line differs from the designed length of the output transmission line by at least 5%.

15. The method of claim 13, further comprising:
connecting the output transmission line to a transmit antenna configured to emit a radio frequency signal,
wherein the designed length of the input transmission line is greater than the designed length of the output transmission line by at least 5%.

16. The method of claim 13, further comprising:
connecting the input transmission line to a receive antenna, such that the input transmission line is configured to receive radio frequency signals received by the receive antenna,
wherein the designed length of the output transmission line is greater than the designed length of the input transmission line by at least 5%.

17. The method of claim 13, wherein the one or more die comprises a low noise amplifier or a high power amplifier.

18. The method of claim 13, wherein the one or more die comprises a monolithic microwave integrated circuit (MMIC) die.

19. A system comprising:
a first enclosure, a first input transmission line within the first enclosure, a first output transmission line within the first enclosure, and a first number of die within the first enclosure and laterally between the first input transmission line and the first output transmission line; and
a second enclosure, a second input transmission line within the second enclosure, a second output transmission line within the second enclosure, and a second number of die within the second enclosure and laterally between the second input transmission line and the second output transmission line, wherein the first and second numbers differ by at least one;
wherein one or more dimensions of the first enclosure is within 2% of corresponding one or more dimensions of the second enclosure.

20. The system of claim 19, wherein:
a sum of length of the first number of die within the first enclosure differs from a sum of length of the second number of die within the second enclosure by at least 5%; and
a sum of length of the first input and first output transmission lines differs from a length of a sum of length of the second input and second output transmission lines by at least 5%.
